(19) United States
(12) Patent Application Publication
(10) Pub. No.: US 2025/0098505 A1
(43) Pub. Date: Mar. 20, 2025

(54) DISPLAY PANEL AND DISPLAY APPARATUS

(71) Applicant: Hubei Yangtze Industrial Innovation Center Of Advanced Display Co., Ltd., Wuhan (CN)

(72) Inventors: Xiaoyang TONG, Wuhan (CN); Yanzi LIU, Wuhan (CN)

(21) Appl. No.: 18/969,316

(22) Filed: Dec. 5, 2024

(30) Foreign Application Priority Data
Aug. 29, 2024 (CN) 202411206906.9

(51) Int. Cl. H10K 59/80; H10K 59/95

(52) U.S. Cl. CPC H10K 59/8792; H10K 59/95

(57) ABSTRACT

A display panel and a display apparatus. The display panel includes: a display area, a substrate, and a light shield layer. The display area includes a light-transmitting display area including a light-sensing element area and at least one transition area, and a normal display area. The light shield layer includes a plurality of light shield portions. An opening area is provided between any two adjacent light shield portions. A ratio of a sum of areas of a plurality of first orthographic projections to an area of the light-sensing element area is a first opening ratio, a ratio of a sum of areas of a plurality of second orthographic projections to an area of the transition area is a second opening ratio, a ratio of a sum of areas of a plurality of third orthographic projections to an area of the normal display area is a third opening ratio.

### CROSS-REFERENCE TO RELATED APPLICATION

The present application claims priority to Chinese Patent Application No. 202411206906.9, filed on Aug. 29, 2024, the content of which is incorporated herein by reference in its entirety.

### TECHNICAL FIELD

The present disclosure relates to the field of display screen and, in particular, to a display panel and a display apparatus.

### BACKGROUND

Organic Light-Emitting Diode (referred to as simply OLED) display technology has the advantages of wide viewing angle, high contrast, fast response, bendability, and flexibility, etc., and has shown obvious advantages in the new generation of displays. In order to further realize the function of an OLED display panel for photographing or shooting, under-panel camera technology was born, and the above function can be achieved by providing light-sensing elements in a part of a light-transmitting display area. However, such a design will affect the normal display effect and usage, due to the visual difference between a light-sensing element area and a normal display area.

Therefore, there is an urgent need for a way to solve the problem in the prior art of affecting the display effect due to the visual difference between the light-sensing element area and the normal display area.

### SUMMARY

The main objective of the present disclosure is to provide a display panel and a display apparatus, to solve the problem in the prior art of affecting the display effect due to the visual difference between the light-sensing element area and the normal display area.

In order to achieve the above objective, according to one aspect of the present disclosure, there is provided a display panel including: a display area, a substrate, and a light shield layer. The display area includes a light-transmitting display area and a normal display area surrounding the light-transmitting display area. The light-transmitting display area includes a light-sensing element area and at least one transition area surrounding the light-sensing element area. The substrate is located on one side of the display area. The light shield layer is located on a side of the display area away from the substrate. The light shield layer includes a plurality of light shield portions arranged at intervals, and an opening area is provided between any two adjacent light shield portions. First orthographic projections of a plurality of the opening areas are located on the substrate in the light-sensing element area, second orthographic projections of the plurality of opening areas are located the substrate in the transition area, third orthographic projections of the plurality of opening areas are located on the substrate in the normal display area. A ratio of a sum of areas of the first orthographic projections to an area of the light-sensing element area is a first opening ratio, a ratio of a sum of areas of the second orthographic projections to an area of the transition area is a second opening ratio, a ratio of a sum of areas of the third orthographic projections to an area of the normal display area is a third opening ratio, and a size of the second opening ratio is between a size of the first opening ratio and a size of the third opening ratio.

In order to achieve the above objective, according to another aspect of the present disclosure, there is provided a display apparatus including the above display panel.

The technical solution of the present disclosure provides a display panel including a display area, a substrate, and a light shield layer. The display area includes a light-transmitting display area and a normal display area surrounding the light-transmitting display area. The light-transmitting display area includes a light-sensing element area and at least one transition area surrounding the light-sensing element area. The light shield layer includes a plurality of light shield portions arranged at intervals, and an opening area is provided between any two adjacent light shield portions. A ratio of a sum of areas of the first orthographic projections to an area of the light-sensing element area is a first opening ratio, a ratio of a sum of areas of the second orthographic projections to an area of the transition area is a second opening ratio, a ratio of a sum of areas of the third orthographic projections to an area of the normal display area is a third opening ratio, and a size of the second opening ratio is between a size of the first opening ratio and a size of the third opening ratio. By providing the transition area surrounding the light-sensing element area in the light-transmitting display area and making the size of the second opening ratio in the transition area between the size of the first opening ratio in the light-sensing element area and the size of the third opening ratio in the normal display area, the difference in reflectivity among the light-sensing element area, the transition area, and the normal display area is slowed down, and in turn, the difference in reflectivity between the light-transmitting display area and other normal display areas is reduced to make it more difficult for the human eye to distinguish, and in turn, the display effect is improved, which solves the problem in the prior art of affecting the display effect due to the difference in display between the light-transmitting display area and the normal display area.

### BRIEF DESCRIPTION OF DRAWINGS

The drawings constituting a part of the present disclosure are used to provide a further understanding of the present disclosure. The exemplary embodiments of the present disclosure and the descriptions thereof are used to explain the present disclosure and do not constitute improper limitations of the present disclosure, in which,

FIG. 1 shows a structural schematic diagram of a display panel provided according to an embodiment of the present disclosure;

FIG. 2 shows a cross-sectional view of the display panel taken along the dotted line in FIG. 1;

FIG. 3 shows a structural schematic diagram of another display panel provided according to an embodiment of the present disclosure;

FIG. 4 shows a cross-sectional view of the display panel taken along the dotted line in FIG. 3;

FIG. 5 shows a structural schematic diagram of a further display panel provided according to an embodiment of the present disclosure;

FIG. 6 shows a cross-sectional view of the display panel taken along the dotted line in FIG. 5;

FIG. 7 shows a structural schematic diagram of another display panel provided according to an embodiment of the present disclosure;

FIG. 8 shows a structural schematic diagram of a further display panel provided according to an embodiment of the present disclosure;

FIG. 9 shows a structural schematic diagram of yet another display panel provided according to an embodiment of the present disclosure;

FIG. 10 shows a structural schematic diagram of another display panel provided according to an embodiment of the present disclosure; and

FIG. 11 shows a structural schematic diagram of a display apparatus provided according to an embodiment of the present disclosure.

The above drawings include the following reference numerals:

10—display area; 101—light-transmitting display area; 102—normal display area; 103—light-sensing element area; 104—transition area; 20—substrate; 30—light shield layer; 301—light shield portion; 302—opening area; D1—first distance; D2—second distance; D3—third distance; D4—fourth distance; 40—display panel.

### DESCRIPTION OF EMBODIMENTS

It should be noted that the following detailed description is illustrative and is intended to provide further explanation of the present disclosure. Unless otherwise specified, all technical and scientific terms used herein have the same meanings as those commonly understood by those skilled in the art to which the present disclosure belongs.

It should be noted that the terms used herein are only for describing specific implementations and are not intended to limit the exemplary implementations according to the present disclosure. As used herein, unless otherwise indicated clearly in the context, a singular form is also intended to include a plural form. In addition, it should be understood that when the terms “include” and/or “comprise” are used in the specification, they indicate the presence of features, steps, operations, devices, assemblies and/or combinations thereof.

It should be understood that when an element (such as a layer, film, area, or substrate) is described as being “on” another element, the element may be directly on another element, or there may be an intermediate element. Moreover, in the specification and claims, when it is described that an element is “connected” to another element, the element may be “directly connected” to another element, or “connected” to another element through a third element.

It should be clear that the described embodiments are only a part of the embodiments of the present disclosure, not all of the embodiments. All other embodiments obtained by those ordinarily skilled in the art based on the embodiments in the present disclosure without creative efforts should fall within the protection scope of the present disclosure.

It should be understood that the term “and/or” used herein is only used to describe the association relationship of associated objects, representing that there can be three relationships. For example, A and/or B can represent: A exists alone, A and B exist at the same time, and B exists alone. In addition, the character “/” herein generally represents that the associated objects before and after it are in an “or” relationship.

In electronic devices, such as smartphones, tablets, etc., optical sensors are important sensing elements for measuring and monitoring ambient light intensity. Optical sensors can play a role in various application scenarios, such as automatically adjusting screen brightness, realizing face recognition function, controlling camera exposure, etc. However, in the actual design and production process, there may be some differences between the hole area and the display area of the optical sensor, thereby affecting the normal display and use of the device. For example, in the packaging process of the optical sensor, the hole area is the light-transmitting part of the optical sensor, and the display area is the light-sensing part of the optical sensor. The differences between the hole area and the display area include size, shape, material, etc. These differences may cause an uneven response of the optical sensor, thereby affecting the normal display and use of the device.

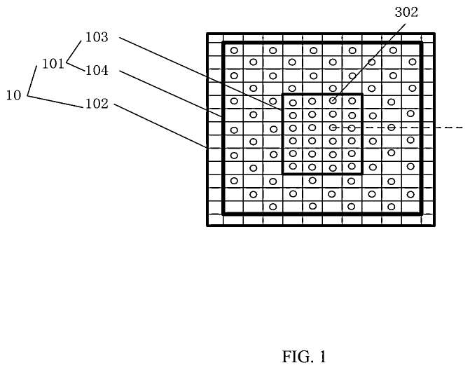

To solve the above problem, embodiments of the present disclosure provide a display panel and a display apparatus, as shown in FIG. 1 to FIG. 9. The display panel includes: a display area 10, a substrate 20, and a light shield layer 30.

The display area 10 includes a light-transmitting display area 101 and a normal display area 102 surrounding the light-transmitting display area 101, a light transmittance of the light-transmitting display area 101 is greater than a light transmittance of the normal display area 102, and reflectivity of the two are also different. The light-transmitting display area 101 may be provided with a camera or a fingerprint recognition module, etc. The light-transmitting display area 101 includes a light-sensing element area 103 and at least one transition area 104 surrounding the light-sensing element area 103. The light-sensing element area 103 is provided with a plurality of light-sensing elements. The light-sensing elements are sensors used for detecting light intensity and are also known as photosensitive sensors or photosensitive elements. This kind of element can detect the light intensity of the surrounding environment and convert this information into electrical signals. These signals can be used for adjusting parameters, such as brightness, color temperature, etc., of the display panel to adapt to different ambient light conditions, improve display effect, and reduce energy consumption. The transition area 104 is located between the light-sensing element area 103 and the normal display area 102.

The material of the substrate 20 may be at least one of glass and quartz material, and is located on one side of the display area 10.

The light shield layer 30, namely a Black Matrix (referred to as simply BM) in the display panel, is used for shielding the display area 10 in the display panel to reduce scattering and reflection of light. This is conducive to improving the contrast and color reproduction of the display panel, and the black matrix can make the pixel spacing in the display panel more uniform, thereby improving the overall visual effect of a screen. The light shield layer 30 is located on a side of the display area 10 away from the substrate 20. The light shield layer 30 includes a plurality of light shield portions 301 arranged at intervals, and an opening area 302 is provided between any two adjacent light shield portions 301. The opening area 302 may be of any shape, e.g., circular, quadrilateral, elliptic, etc. First orthographic projections of the opening areas 302 are located on the substrate 20 in the light-sensing element area 103, and the first orthographic projections can be used for representing the size of the opening areas 302 in the light-sensing element area 103. Second orthographic projections of the opening areas 302 are located on the substrate 20 in the transition area 104, and the second orthographic projections can be used for representing the size of the opening areas 302 in the transition area 104. Third orthographic projections of the opening areas 302are located on the substrate 20 in the normal display area 102, and the third orthographic projections can be used for representing the size of the opening areas 302 in the normal display area 102. A ratio of a sum of areas of the first orthographic projections to an area of the light-sensing element area 103 is a first opening ratio, and the first opening ratio can represent the light transmittance of the light-sensing element area 103. A ratio of a sum of areas of the second orthographic projections to an area of the transition area 104 is a second opening ratio, and the second opening ratio can represent the light transmittance of the transition area 104. A ratio of a sum of areas of the third orthographic projections to an area of the normal display area 102 is a third opening ratio, and the third opening ratio can represent the light transmittance of the normal display area 102. A size of the second opening ratio is between a size of the first opening ratio and a size of the third opening ratio. That is, the light transmittance of the transition area 104 is between the light transmittance of the light-sensing element area 103 and the light transmittance of the normal display area 102, which can realize a gradual transition of light transmittance from the light-sensing element area 103 to the normal display area 102, which in turn reduces the difference in reflectivity between the light-transmitting display area 101 and other normal display areas 102.

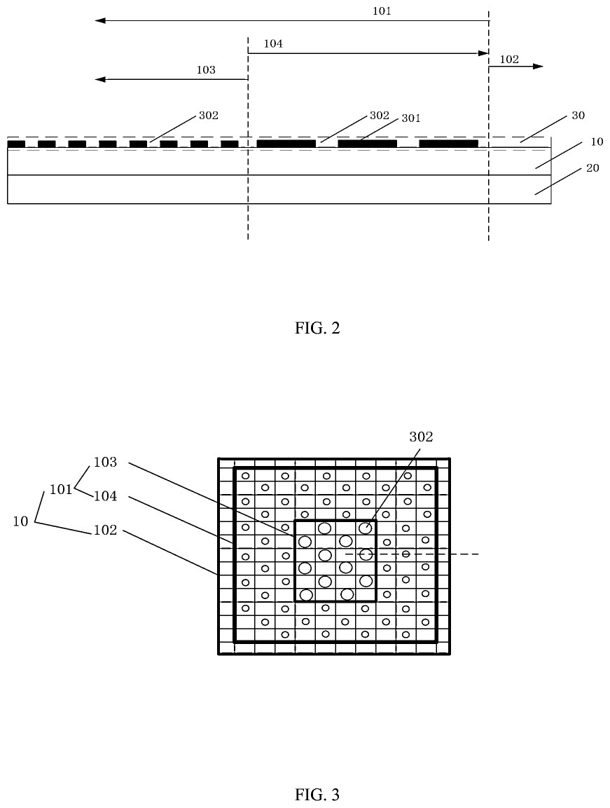

A cross-sectional view taken along the dotted line in FIG. 1 is shown in FIG. 2, in which, the display area 10 includes the light-transmitting display area 101 and the normal display area 102 surrounding the light-transmitting display area 101, and the light-transmitting display area 101 includes the light-sensing element area 103 and the at least one transition area 104 surrounding the light-sensing element area 103. The substrate 20 is located on one side of the display area 10. The light shield layer 30 includes the plurality of light shield portions 301 arranged at intervals, and the opening area 302 is provided between any two adjacent light shield portions 301. In the present disclosure, the sizes of the light shield portions 301 are not limited, and may be different in the light-sensing element area 103 and the transition area 104, as shown in FIG. 2, or may be the same in the light-sensing element area 103 and the transition area 104.

In the above embodiment, there is provided a display panel including the display area, the substrate, and the light shield layer. The display area includes the light-transmitting display area and the normal display area surrounding the light-transmitting display area, and the light-transmitting display area includes the light-sensing element area and the at least one transition area surrounding the light-sensing element area. The light shield layer includes the plurality of light shield portions arranged at intervals, and the opening area is provided between any two adjacent light shield portions. The ratio of the sum of the areas of the first orthographic projections to the area of the light-sensing element area is the first opening ratio, the ratio of the sum of the areas of the second orthographic projections to the area of the transition area is the second opening ratio, the ratio of the sum of the areas of the third orthographic projections to the area of the normal display area is the third opening ratio, and the size of the second opening ratio is between the size of the first opening ratio and the size of the third opening ratio. By providing the transition area surrounding the light-sensing element area in the light-transmitting display area and making the size of the second opening ratio in the transition area between the size of the first opening ratio in the light-sensing element area and the size of the third opening ratio in the normal display area, the difference in reflectivity among the light-sensing element area, the transition area, and the normal display area is slowed down, and in turn, the difference in reflectivity between the light-transmitting display area and other normal display areas is reduced to make it more difficult for the human eye to distinguish, and in turn, the display effect is improved, which solves the problem in the prior art of affecting the display effect due to the difference in display between the light-transmitting display area and the normal display area.

In order to further reduce the difference in reflectivity between the light-transmitting display area and other normal display areas, the first opening ratio is greater than the third opening ratio. That is, the second opening ratio is greater than the third opening ratio and less than the first opening ratio. The setting can further meet the display requirements of the non-light-transmitting display in the normal display area.

Specifically, where the areas of the light-sensing element area, the transition area, and the normal display area are different, the number of the opening areas in each of the areas is not limited, as long as the requirements for the opening ratios can be met. Where the areas of the light-sensing element area, the transition area, and the normal display area are the same, the number of the opening areas in the light-sensing element area is the largest, followed by the number of the opening areas in the transition area, and the number of the opening areas in the normal display area is the smallest. That is, the number of the opening areas in the light-sensing element area is greater than the number of the opening areas in the transition area and greater than the number of the opening areas in the normal display area. The number of the opening areas in the normal display area is 0, and thus the light transmittance is generally 0. Therefore, the first opening ratio is greater than the third opening ratio.

In some optional embodiments, the ratio of the second opening ratio to the first opening ratio is in a range of 0.2-0.6. The setting of the opening ratios can further enhance the effect of transition from the light-sensing element area to the normal display area and further reduce the display difference between the two areas.

In a practical application, the ratio of the second opening ratio to the first opening ratio should not be too small or too large. Where the ratio of the second opening ratio to the first opening ratio is too small, that is, less than 0.2, the transition of light transmittance from the light-sensing element area to the transition area can be ensured to be relatively natural, but the effect of the transition of light transmittance from the transition area to the normal display area may be affected. Where the ratio of the second opening ratio to the first opening ratio is too large, that is, greater than 0.6, the effect of the transition of light transmittance from the light-sensing element area to the transition area may be affected. Where the ratio of the second opening ratio to the first opening ratio is 0.5, the effect of the transition of light transmittance from the light-sensing element area to the transition area and the effect of the transition of light transmittance from the transition area to the normal display area can be ensured at the same time. For example, if the areas of the light-sensing element area and the transition area are the same and the number of the opening areas in the transition area is 4, then the number of the opening areas in the light-sensing element area is 8.

In some optional embodiments, as shown in FIG. 3, a size of an area of a single second orthographic projection is between a size of an area of a single first orthographic projection and a size of an area of a single third orthographic projection. That is, the area of one opening area 302 in the transition area 104 is between the area of one opening area 302 in the light-sensing element area 103 and the area of one opening area 302 in the normal display area 102. The setting can reduce the display difference between the light-sensing element area 103 and the normal display area 102 only by changing the sizes of the areas of the opening areas 302 in the light-sensing element area 103, the transition area 104, and the normal display area 102, so that the process difficulty of the display panel can be further reduced.

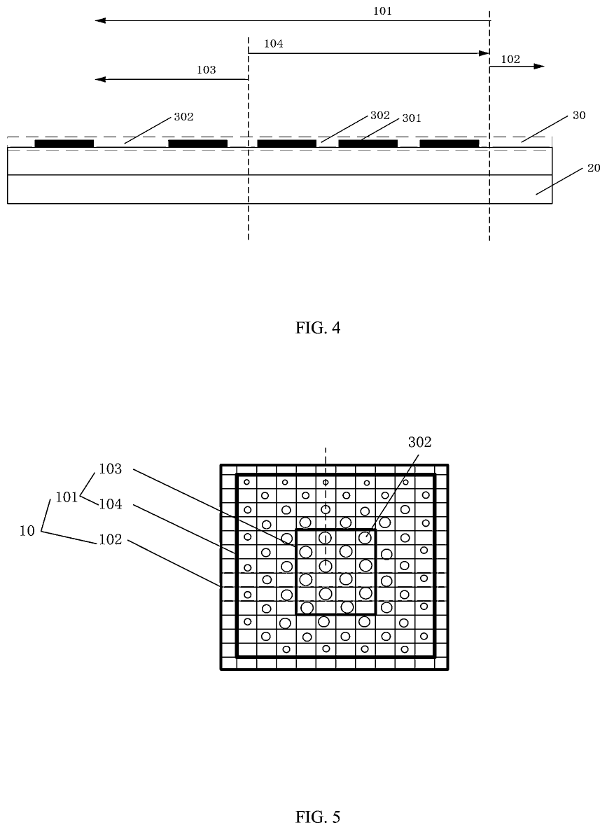

A cross-sectional view taken along the dotted line in FIG. 3 is shown in FIG. 4, in which, the display area 10 includes the light-transmitting display area 101 and the normal display area 102 surrounding the light-transmitting display area 101. The light-transmitting display area 101 includes the light-sensing element area 103 and the at least one transition area 104 surrounding the light-sensing element area 103. The substrate20 is located on one side of the display area 10. The light shield layer 30 is located on a side of the display area 10 away from the substrate 20. The light shield layer 30 includes a plurality of light shield portions 301 arranged at intervals, and the opening area 302 is provided between any two adjacent light shield portions 301. The area of one opening area 302 in the transition area 104 is between the area of one opening area 302 in the light-sensing element area 103 and the area of one opening area 302 in the normal display area 102. In the present disclosure, the sizes of the light shield portions 301 are not limited, and may be the same in the light-sensing element area 103 and the transition area 104, as shown in FIG. 4, or may be different in the light-sensing element area 103 and the transition area 104.

In a practical application, the numbers of the opening areas in the light-sensing element area, the transition area, and the normal display area may be the same or different. That is, the gradual change of the opening ratio can be achieved in the following ways: in a first way, the numbers of the opening areas in the light-sensing element area, the transition area, and the normal display area are the same, and the size of the area of the single second orthographic projection is between the size of the area of the single first orthographic projection and the size of the area of the single third orthographic projection; and in a second way, the size of the area of the single second orthographic projection is between the size of the area of the single first orthographic projection and the size of the area of the single third orthographic projection, and the numbers of the opening areas in the light-sensing element area, the transition area, and the normal display area are different, but the numbers of the opening areas in the light-sensing element area, the transition area, and the normal display area meet the condition that the second opening ratio is greater than the third opening ratio and less than the first opening ratio.

In order to further reduce the difference in reflectivity between the light-transmitting display area and other normal display areas, the area of the single first orthographic projection is larger than the area of the single third orthographic projection. That is, the area of the projection of an opening area corresponding to the light-sensing element area onto the substrate is larger than the area of the projection of an opening area corresponding to the normal display area onto the substrate.

Specifically, since the normal display area is a non-light-transmitting display area, the area of the opening area in the normal display area is 0, and thus the light transmittance is generally 0. Therefore, the area of the single first orthographic projection is larger than the area of the single third orthographic projection. Since the size of the area of the single second orthographic projection is between the size of the area of the single first orthographic projection and the size of the area of the single third orthographic projection and the area of the single first orthographic projection is larger than the area of the single third orthographic projection, the area of the single opening area in the light-sensing element area is the largest, followed by the area of the single opening area in the transition area, and the area of the single opening area in the normal display area is the smallest. In a direction from the light-sensing element area to the transition area and from the transition area to the normal display area, the areas of the individual opening areas progressively decrease, and the light transmittances also progressively decrease, which can further enhance the effect of transition from the light-sensing element area to the transition area and the effect of transition from the transition area to the normal display area, and in turn, further enhancing the effect of transition from the light-sensing element area to the normal display area.

A ratio of the area of the single second orthographic projection to the area of the single first orthographic projection is in the range of 0.2-0.6. The setting of the area of the single opening area can further enhance the effect of transition from the light-sensing element area to the normal display area, and further reduce the display difference between the two areas.

In a practical application, the ratio of the area of the single second orthographic projection to the area of the single first orthographic projection should not be too small or too large. Where the ratio of the area of the single second orthographic projection to the area of the single first orthographic projection is too small, the transition of light transmittance from the light-sensing element area to the transition area can be ensured to be relatively natural, but the effect of the transition of light transmittance from the transition area to the normal display area may be affected. Where the ratio of the area of the single second orthographic projection to the area of the single first orthographic projection is too large, the effect of the transition of light transmittance from the light-sensing element area to the transition area may be affected. Where the ratio of the area of the single second orthographic projection to the area of the single first orthographic projection is 0.5, the effect of the transition of light transmittance from the light-sensing element area to the transition area and the effect of the transition of light transmittance from the transition area to the normal display area can be ensured at the same time. The areas of the second orthographic projections in the transition area may be all the same or may not be all the same. Where the areas of the individual second orthographic projections in the transition area are different, the area of the single second orthographic projection can be obtained by calculating the average area of the second orthographic projections. The areas of the first orthographic projections in the light-sensing element area may be all the same or may not be all the same. Where the areas of the individual first orthographic projections in the light-sensing element area are different, the area of the single first orthographic projection can be obtained by calculating the average area of the first orthographic projections.

As shown in FIG. 5, the sizes of the areas of the second orthographic projections progressively decrease in the direction from the light-sensing element area 103 to the normal display area 102. The setting can further improve the transition of light transmittance in the transition area.

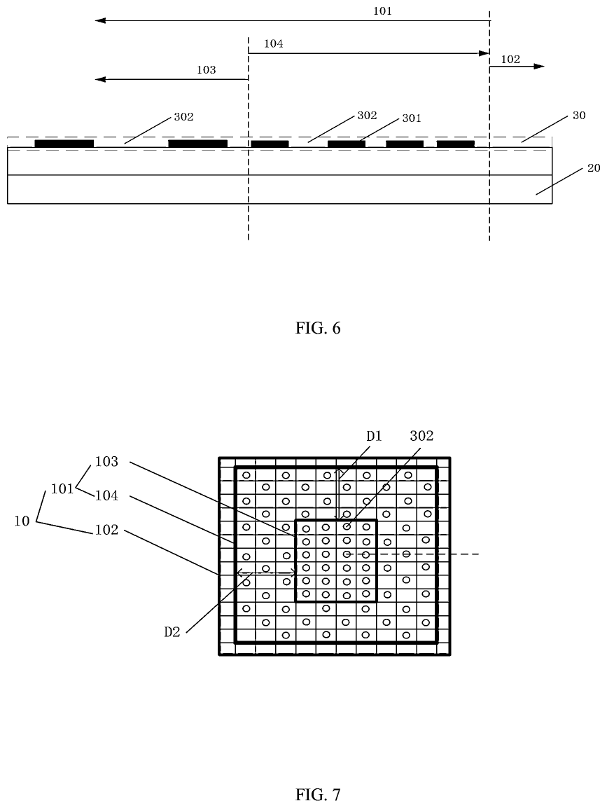

A cross-sectional view taken along the dotted line in FIG. 5 is shown in FIG. 6, in which, the display area 10 includes the light-transmitting display area 101 and the normal display area 102 surrounding the light-transmitting display area 101, and the light-transmitting display area 101 includes the light-sensing element area 103 and the at least one transition area 104 surrounding the light-sensing element area 103. The substrate 20 is located on one side of the display area 10. The light shield layer 30 is located on a side of the display area 10 away from the substrate 20. The light shield layer 30 includes the plurality of light shield portions 301 arranged at intervals, and the opening area 302 is provided between any two adjacent light shield portions 301. The sizes of the areas of the second orthographic projections progressively decrease in the direction from the light-sensing element area 103 to the normal display area 102. In the present disclosure, the sizes of the light shield portions 301 are not limited, and may be the same in the light-sensing element area 103 and the transition area 104, as shown in FIG. 6, or may be different in the light-sensing element area 103 and the transition area 104.

Specifically, the areas of the opening areas in the transition area are different, and the area of the largest opening area in the transition area is smaller than the area of the smallest opening area in the light-sensing display area. The progressive decreasing setting can be provided in a certain direction from the light-sensing element area to the normal display area, and can also be provided in every direction from the light-sensing element area to the normal display area. In addition, the progressive decreasing setting of the sizes of the areas of the second orthographic projections can be uniformly progressive decreasing or non-uniformly progressive decreasing.

An orthographic projection of the transition area onto the substrate is a first pattern, an orthographic projection of the light-sensing element area onto the substrate is a second pattern, and a shape of the first pattern and a shape of the second pattern is the same. That is, the first pattern and the second pattern have the same shape but different sizes. Therefore, the first pattern and the second pattern are similar, which can further enhance the display transition effect from the light-sensing element area to the transition area.

Specifically, since the first pattern and the second pattern are similar and the shapes of the edges of the light-sensing element area and the transition area are also the same, the display difference from the light-sensing element area to the transition area can be reduced. In the present disclosure, the shape of the first pattern and the shape of the second pattern are not particularly limited.

In order to further increase the display brightness of the display panel, the shape of the first pattern and the shape of the second pattern are circular, elliptical, or quadrilateral.

In a practical application, where the shape of the first pattern and the shape of the second pattern are circular or elliptical, the edge of the light shield portion is a curve. Where the shape of the first pattern and the shape of the second pattern are quadrilateral, the edge of the light shield portion is a straight line. Under the condition that the diameter is the same and where the shape of the first pattern and the shape of the second pattern are quadrilateral, the areas of the transition area and the light-sensing element area are the largest, which in turn increases the areas of the opening areas and the display brightness of the display panel.

As shown in FIG. 7, in a first direction, the transition area 104 has a first boundary and a second boundary. The second boundary is located on a side of the first boundary away from the light-sensing element area 103. That is, the first boundary is the inner boundary of the transition area 104 in the first direction, and the second boundary is the outer boundary of the transition area 104 in the first direction. A distance between a boundary of the light-sensing element area 103 and the second boundary is a first distance D1, and the boundary of the light-sensing element area 103 in the first direction may or may not coincide with the first boundary. In a second direction, the transition area 104 has a third boundary and a fourth boundary. The fourth boundary is located on a side of the third boundary away from the light-sensing element area 103. That is, the third boundary is the inner boundary of the transition area 104 in the second direction, and the fourth boundary is the outer boundary of the transition area 104 in the second direction. A distance between the boundary of the light-sensing element area 103 and the fourth boundary is a second distance D2, and the boundary of the light-sensing element area 103 in the second direction may or may not coincide with the third boundary. The values of the first distance D1 and the second distance D2 are in a range of 400-1000 ρm, and the first distance D1 may or may not be equal to the second distance D2. The first direction intersects the second direction, and the first direction and the second direction are perpendicular to a thickness direction of the substrate.

In a further embodiment, the first direction and the second direction may intersect but not be perpendicular to each other, or they may be perpendicular to each other. The first distance or the second distance should not be too small or too large. Where the first distance or the second distance is too small, i.e., less than 400 μm, the area of the transition area may be too small, and the distance from the light-sensing element area to the normal display area may be too short, which affects the effect of transition from the light-sensing element area to the normal display area. Where the first distance or the second distance is too large, i.e., greater than 1000 μm, the area of the transition area may be too large, which in turn affects the area of the display area and fails to meet the demand for miniaturization of the display panel.

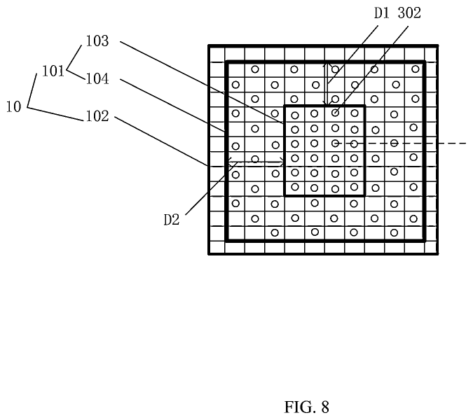

As shown in FIG. 8, the first distance D1 is equal to the second distance D2. That is, the distance between the boundary of the light-sensing element area 103 and the second boundary is the same in both the first direction and the second direction. This structure can further reduce the display difference from the light-sensing element area to the normal display area in the first direction and the second direction.

In addition, the distance between the boundary of the light-sensing element area and the second boundary is the same in both the first direction and the second direction. Where the boundary of the light-sensing element area in the first direction coincides with the first boundary and the boundary of the light-sensing element area in the second direction coincides with the third boundary, it is indicated that the width of the transition area is also equal in both the first direction and the second direction. Where the boundary of the light-sensing element area in the first direction does not coincide with the first boundary or the boundary of the light-sensing element area in the second direction does not coincide with the third boundary, it is indicated that the distance between the light-sensing element area and the outer boundary of the transition area in the first direction and the distance between the light-sensing element area and the outer boundary of the transition area in the second direction are equal.

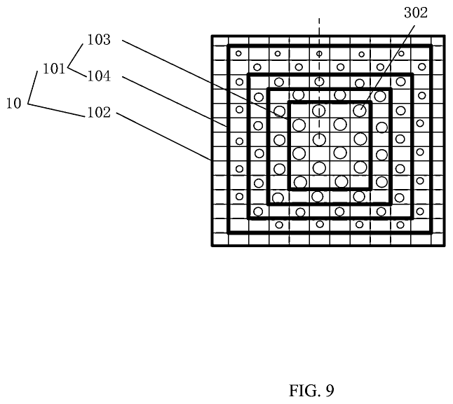

In a specific implementation process, as shown in FIG. 9, a plurality of transition areas 104 are distributed along the direction from the light-sensing element area 103 to the normal display area 102, and the areas of the second orthographic projections in the plurality of transition areas 104 progressively decrease. The areas of the second orthographic projections in the plurality of transition areas 104 progressively decreasing can reduce the display difference between the light-sensing element area and the transition areas and the display difference between the transition areas and the normal display area, which in turn further improves the effect of transition from the light-sensing element area to the normal display area.

Specifically, the greater the number of transition areas is, the better the effect of the transition display is. However, due to the limitation of the size of the display panel, the number of the transition areas cannot be infinite. The widths of the plurality of transition areas may be the same or different. The geometric center points of the plurality of transition areas may be the same or different. The areas of the second orthographic projections in the transition areas progressively decreasing may occur in the following two ways: in the first way, within one transition area, in the direction from the light-sensing element area to the normal display area, the areas of the second orthographic projections are different, the areas of the second orthographic projections progressively decreases, and the areas of the second orthographic projections in any two adjacent transition areas progressively decrease; and in the second way, within one transition area, the areas of the second orthographic projections are the same, and the areas of the second orthographic projections in any two adjacent transition areas progressively decrease.

In a further embodiment, along the direction from the light-sensing element area to the normal display area, the areas of the second orthographic projections in two adjacent transition areas are a first area and a second area, respectively, and a ratio of the second area to the first area is in a range of 0.4-0.6. The setting of the opening ratio can further improve the transition effect between the two adjacent transition areas in the direction from the light-sensing element area to the normal display area, and further reduce the display difference between the two.

Specifically, the ratio of the second area to the first area should not be too small or too large. Where the ratio of the second area to the first area is too small, i.e., less than 0.4, the transition of light transmittance between the two adjacent transition areas in the direction from the light-sensing element area to the normal display area can be ensured to be relatively natural, but the effect of the transition of light transmittance from the transition areas to the normal display area may be affected. Where the ratio of the second area to the first area is too large, i.e., greater than 0.6, the effect of the transition of light transmittance between the two adjacent transition areas in the direction from the light-sensing element area to the normal display area may be affected. Where the ratio of the second area to the first area is 0.5, the effect of the transition of light transmittance between the two adjacent transition areas in the direction from the light-sensing element area to the normal display area and the effect of the transition of light transmittance from the transition areas to the normal display area can be ensured simultaneously.

In another embodiment, a plurality of transition areas are distributed along the direction from the light-sensing element area to the normal display area, and the shapes of the plurality of first patterns are the same. That is, the shapes of the orthographic projections of the transition areas onto the substrate are the same. The setting can further ensure that the shapes of the edges of the transition areas are the same, and further enhance the display effect of the transition between the two adjacent transition areas.

In a practical application, the shapes of the first patterns are circular, elliptic or quadrilateral. In addition, the geometric center points of the plurality of transition areas may be the same or different.

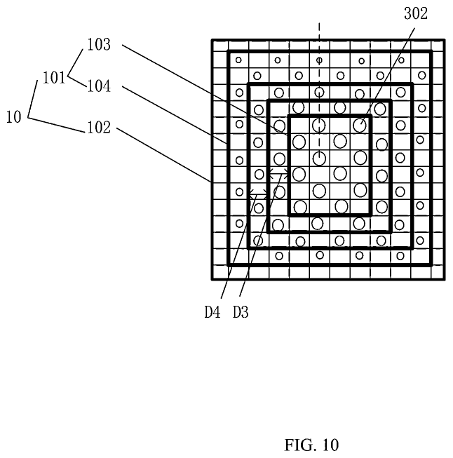

In a specific implementation process, as shown in FIG. 10, a plurality of transition areas 104 are distributed along the direction from the light-sensing element area 103 to the normal display area 102. Each of the transition areas 104 has a fifth boundary and a sixth boundary. The sixth boundary is located on a side of the fifth boundary away from the light-sensing element area 103. That is, the fifth boundary is the inner boundary of the transition area 104, and the sixth boundary is the outer boundary of the transition area 104. The distance between the boundary of the light-sensing element area 103 and the sixth boundary of the adjacent transition area 104 is a third distance D3. The boundary of the light-sensing element area 103 may or may not coincide with the fifth boundary. The distance between the sixth boundaries of the two adjacent transition areas 104 is a fourth distance D4. The fifth boundary of one of the two adjacent transition areas 104 may or may not coincide with the sixth boundary of the other of the two adjacent transition areas 104. The values of the third distance D3 and the fourth distance D4 are in a range of 200-500 μm. The third distance D3 may or may not be equal to the fourth distance D4.

Specifically, the shapes of the fifth boundary and the sixth boundary may be regular or irregular.

In a further embodiment, the third distance is equal to the fourth distance. That is, the distance between the boundary of the light-sensing element area and the sixth boundary of the adjacent transition area is the same as the sixth boundaries of the two adjacent transition areas. This structure can further reduce the display difference from the light-sensing element area to the transition area and the display difference between the two adjacent transition areas.

Specifically, where the boundary of the light-sensing element area coincides with the fifth boundary and the fifth boundary of one of the two adjacent transition areas and the sixth boundary of the other of the two adjacent transition areas coincide with each other, it is indicated that the widths of the plurality of transition areas are the same, and a distribution similar to a concentric pattern can be formed. Where the boundary of the light-sensing element area does not coincide with the fifth boundary or the fifth boundary of one of the two adjacent transition areas and the sixth boundary of the other of the two adjacent transition areas do not coincide with each other, the distance between the sixth boundary of the transition area closest to the light-sensing element area and the boundary of the light-sensing element area and the distance between the adjacent sixth boundaries are the same.

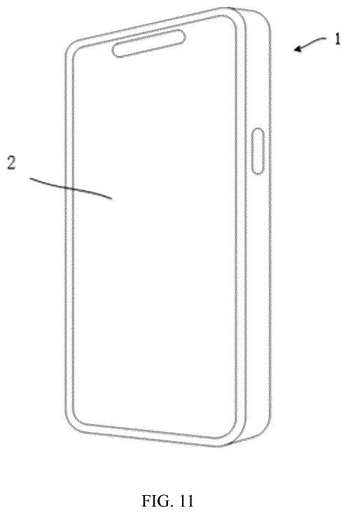

According to an embodiment of the present disclosure, as shown in FIG. 11, there is further provided a display apparatus including any one of the above-described display panels 40.

From the above description, it can be seen that the above embodiments of the present disclosure have achieved the following technical effects.
(1) The display panel of the present disclosure include the display area, the substrate, and the light shield layer. The display area includes the light-transmitting display area and the normal display area surrounding the light-transmitting display area, and the light-transmitting display area includes the light-sensing element area and the at least one transition area surrounding the light-sensing element area. The light shield layer includes the plurality of light shield portions arranged at intervals, and the opening area is provided between any two adjacent light shield portions. The ratio of the sum of the areas of the first orthographic projections to the area of the light-sensing element area is the first opening ratio, the ratio of the sum of the areas of the second orthographic projections to the area of the transition area is the second opening ratio, the ratio of the sum of the areas of the third orthographic projections to the area of the normal display area is the third opening ratio, and the size of the second opening ratio is between the size of the first opening ratio and the size of the third opening ratio. By providing the transition area surrounding the light-sensing element area in the light-transmitting display area and making the size of the second opening ratio in the transition area between the size of the first opening ratio in the light-sensing element area and the size of the third opening ratio in the normal display area, the difference in reflectivity among the light-sensing element area, the transition area, and the normal display area is slowed down, and in turn, the difference in reflectivity between the light-transmitting display area and other normal display areas is reduced to make it more difficult for the human eye to distinguish, and in turn, the display effect is improved, which solves the problem in the prior art of affecting the display effect due to the difference in display between the light-transmitting display area and the normal display area.
(2) The display apparatus of the present disclosure includes the display panel including the display area, the substrate, and the light shield layer. The display area includes the light-transmitting display area and the normal display area surrounding the light-transmitting display area, and the light-transmitting display area includes the light-sensing element area and the at least one transition area surrounding the light-sensing element area. The light shield layer includes the plurality of light shield portions arranged at intervals, and the opening area is provided between any two adjacent light shield portions. The ratio of the sum of the areas of the first orthographic projections to the area of the light-sensing element area is the first opening ratio, the ratio of the sum of the areas of the second orthographic projections to the area of the transition area is the second opening ratio, the ratio of the sum of the areas of the third orthographic projections to the area of the normal display area is the third opening ratio, and the size of the second opening ratio is between the size of the first opening ratio and the size of the third opening ratio. By providing the transition area surrounding the light-sensing element area in the light-transmitting display area and making the size of the second opening ratio in the transition area between the size of the first opening ratio in the light-sensing element area and the size of the third opening ratio in the normal display area, the difference in reflectivity among the light-sensing element area, the transition area, and the normal display area is slowed down, and in turn, the difference in reflectivity between the light-transmitting display area and other normal display areas is reduced to make it more difficult for the human eye to distinguish, and in turn, the display effect is improved, which solves the problem in the prior art of affecting the display effect due to the difference in display between the light-transmitting display area and the normal display area.

The above description is merely for the preferred embodiments of the present disclosure and is not intended to limit the present disclosure. For those skilled in the art, the present disclosure may have various modifications and variations. Any modification, equivalent replacement, improvement, etc. made within the spirit and principle of the present disclosure shall be included in the protection scope of the present disclosure.

What is claimed is:

1. A display panel, comprising:
a display area comprising a light-transmitting display area and a normal display area surrounding the light-transmitting display area, wherein the light-transmitting display area comprises a light-sensing element area and at least one transition area surrounding the light-sensing element area;
a substrate located on one side of the display area;
a light shield layer located on a side of the display area away from the substrate, wherein the light shield layer comprises a plurality of light shield portions arranged at intervals, and an opening area is provided between any two adjacent light shield portions, and wherein first orthographic projections of a plurality of the opening areas are located on the substrate in the light-sensing element area, second orthographic projections of the plurality of opening areas are located the substrate in the transition area, third orthographic projections of the plurality of opening areas are located on the substrate in the normal display area, a ratio of a sum of areas of the first orthographic projections to an area of the light-sensing element area is a first opening ratio, a ratio of a sum of areas of the second orthographic projections to an area of the transition area is a second opening ratio, a ratio of a sum of areas of the third orthographic projections to an area of the normal display area is a third opening ratio, and a size of the second opening ratio is between a size of the first opening ratio and a size of the third opening ratio.

2. The display panel according to claim 1, wherein the first opening ratio is greater than the third opening ratio.

3. The display panel according to claim 1, wherein a ratio of the second opening ratio to the first opening ratio is in a range of 0.2-0.6.

4. The display panel according to claim 1, wherein a size of an area of a single second orthographic projection is between a size of an area of a single first orthographic projection and a size of an area of a single third orthographic projection.

5. The display panel according to claim 4, wherein the size of the area of the single first orthographic projection is greater than the size of the area of the single third orthographic projection.

6. The display panel according to claim 4, wherein a ratio of the area of the single second orthographic projection to the area of the single first orthographic projection is in a range of 0.2-0.6.

7. The display panel according to claim 4, wherein sizes of the areas of the second orthographic projections progressively decrease in a direction from the light-sensing element area to the normal display area.

8. The display panel according to claim 1, wherein an orthographic projection of the transition area onto the substrate is a first pattern, an orthographic projection of the light-sensing element area onto the substrate is a second pattern, and a shape of the first pattern and a shape of the second pattern is the same.

9. The display panel according to claim 8, wherein the shape of the first pattern and the shape of the second pattern are circular, elliptical, or quadrilateral.

10. The display panel according to claim 1, wherein in a first direction, the transition area has a first boundary and a second boundary, the second boundary is located on a side of the first boundary away from the light-sensing element area, and a distance between a boundary of the light-sensing element area and the second boundary is a first distance; in a second direction, the transition area has a third boundary and a fourth boundary, the fourth boundary is located on a side of the third boundary away from the light-sensing element area, and a distance between the boundary of the light-sensing element area and the fourth boundary is a second distance; and values of the first distance and the second distance is in a range of 400-1000 μm; and wherein the first direction and the second direction intersect each other, and the first direction and the second direction are perpendicular to a thickness direction of the substrate.

11. The display panel according to claim 10, wherein the first distance is equal to the second distance.

12. The display panel according to claim 1, wherein a plurality of transition areas are distributed along a direction from the light-sensing element area to the normal display area, and the areas of the second orthographic projections in the plurality of transition areas progressively decrease.

13. The display panel according to claim 12, wherein the areas of the second orthographic projections in two adjacent transition areas are a first area and a second area, respectively, along the direction from the light-sensing element area to the normal display area, and a ratio of the second area to the first area is in a range of 0.4-0.6.

14. The display panel according to claim 1, wherein a plurality of transition areas are distributed along a direction from the light-sensing element area to the normal display area, and a plurality of the second opening ratios in the plurality of transition areas progressively decrease.

15. The display panel according to claim 10, wherein the second opening ratios in two adjacent transition areas are a first ratio and a second ratio, respectively, along a direction from the light-sensing element area to the normal display area, and a ratio of the second ratio to the first ratio is in a range of 0.4-0.6.

16. The display panel according to claim 8, wherein a plurality of transition areas are distributed along a direction from the light-sensing element area to the normal display area, and the shapes of a plurality of the first patterns are the same.

17. The display panel according to claim 1, wherein a plurality of transition areas are distributed along a direction from the light-sensing element area to the normal display area, each of the transition areas has a fifth boundary and a sixth boundary, the sixth boundary is located on a side of the fifth boundary away from the light-sensing element area, a distance between a boundary of the light-sensing element area and the sixth boundary of the transition area adjacent thereto is a third distance, a distance between the sixth boundaries of two adjacent transition areas is a fourth distance, and values of the third distance and the fourth distance are in a range of 200-500 μm.

18. The display panel according to claim 17, wherein the third distance is equal to the fourth distance.

19. A display apparatus, comprising a display panel, wherein the display panel comprises:
a display area comprising a light-transmitting display area and a normal display area surrounding the light-transmitting display area, wherein the light-transmitting display area comprises a light-sensing element area and at least one transition area surrounding the light-sensing element area;
a substrate located on one side of the display area;
a light shield layer located on a side of the display area away from the substrate, wherein the light shield layer comprises a plurality of light shield portions arranged at intervals, and an opening area is provided between any two adjacent light shield portions, and wherein first orthographic projections of a plurality of the opening areas are located on the substrate in the light-sensing element area, second orthographic projections of the plurality of opening areas are located the substrate in the transition area, third orthographic projections of the plurality of opening areas are located on the substrate in the normal display area, a ratio of a sum of areas of the first orthographic projections to an area of the light-sensing element area is a first opening ratio, a ratio of a sum of areas of the second orthographic projections to an area of the transition area is a second opening ratio, a ratio of a sum of areas of the third orthographic projections to an area of the normal display area is a third opening ratio, and a size of the second opening ratio is between a size of the first opening ratio and a size of the third opening ratio.
